(19) United States
(12) Patent Application Publication
(10) Pub. No.: US 2010/0061175 A1
(43) Pub. Date: Mar. 11, 2010

(54) CIRCUIT AND METHOD FOR DRIVING WORD LINE

(76) Inventor: Seung-Lo KIM, Gyeonggi-do (KR)

Correspondence Address: IP & T Law Firm PLC, 7700 Little River Turnpike, Suite 207, Annandale, VA, 22003, US

(21) Appl. No.: 12/344,106

(22) Filed: Dec. 24, 2008

(30) Foreign Application Priority Data
Sep. 8, 2008 (KR) 10-2008-0088290

(51) Int. Cl. G11C 5/14; G11C 8/08

(52) U.S. Cl. 365/226; 365/230.06

(57) ABSTRACT

A method for activating a word line inactivated with a negative voltage includes applying an intermediate voltage to the word line; and applying an activation voltage to the word line, wherein the intermediate voltage has a voltage level between the activation voltage and the negative voltage. A circuit and a method for driving a word line, and the circuit for driving the word line includes a first driving device for driving the word line with an activation voltage; a second driving device for driving the word line with an inactivation voltage; and a third driving device for driving the word line with a voltage between the activation voltage and the inactivation voltage.

### CROSS-REFERENCE TO RELATED APPLICATION

The present invention claims priority of Korean patent application number 10-2008-0088290, filed on Sep. 8, 2008, which is incorporated by reference in its entirety.

### BACKGROUND OF THE INVENTION

The present invention relates to relates to a circuit and a method for driving a word line used in a semiconductor memory device, and more particularly, to a technology capable of reducing consumption of a current needed for driving the word line.

A semiconductor memory device includes a plurality of memory cells to store data and a basic shape of the memory cell is as shown in FIG. 1.

A word line WL is a signal line for selecting and activating the memory cell and is selected by a row address.

If a specific word line WL is selected by the address, a voltage of the word line WL is changed to a high voltage. Therefore, a cell transistor T is turned on and primary data are transmitted while data stored at a storage node S are charge-shared with a bit line BL as a signal line used in inputting/outputting the data to primarily transmit the data. This operation is referred to as an active operation of a memory device.

If a pre-charge command is applied, the voltage of the word line WL which is selected in the active operation is changed to a low voltage, the transistor T is turned off and the data is stored at the storage node S.

Even while the word line WL is inactivated due to the low voltage to turn off the transistor T, charge leakage occurs from the storage node S. Therefore, the data stored at the storage node S is lost with the passage of time. In order to prevent data loss, a refresh operation is needed to re-store the data which is stored at the storage node S at predetermined time intervals, wherein a temporal characteristic until the data is physically lost from the storage node S is referred to as a refresh characteristic.

With improvement of an integration technology of the memory device, an interval between the memory cell and an adjacent portion narrows more and more, thereby increasing the charge leakage. In addition, since the capacity of a capacitor C is reduced, the refresh characteristic is gradually deteriorated. To address the problem, a threshold voltage of the transistor T is partially kept high in order to reduce the charge leakage. However, this method increases the time needed to store the data.

A negative word line scheme to address the problem is a method using a negative voltage VBBW below a ground voltage VSS instead of the ground voltage VSS as an inactivation voltage of the word line WL. The negative word line scheme has an advantage to prevent increment of the time needed to store the data by regulating the leakage by using a VGS relationship of the transistor T without increasing the threshold voltage of the transistor T.

Only the negative word line scheme has a disadvantage of increasing current consumption due to increment of a voltage change range of the word line WL. In other words, since the voltage change range increases in activating and inactivating the word lines WL, the current consumption increases.

As an activation voltage of the word line WL, a power voltage VDD is used. However, a pumping voltage VPP above the power voltage VDD is also used in order to reduce the time needed to increase the voltage of the word line WL in activation and to make sure the transistor T turns on. In case that the negative word line scheme is used and the pumping voltage VPP is used as the activation voltage of the word line WL, the voltage of the word line WL is changed in a wide range from the negative voltage VBBW to the pumping voltage VPP according to the activation and the inactivation. In this case, it is natural that more current is consumed to drive the word line WL.

Since the pumping voltage VPP is above the power voltage VDD and the negative voltage VBBW is below the ground voltage VSS, VPP is a voltage generated through an internal pumping operation of the memory device. This pumping operation is inefficient in terms of current consumption and thus more current is consumed to maintain levels of the pumping voltage VPP and the negative voltage VBBW. Therefore, a technology is needed to reduce the consumption of the current needed for driving the word line WL.

FIG. 2 is a schematic diagram illustrating a conventional word line driving circuit.

The word line driving circuit includes a driving device 210 for activating a word line WL and a driving device 220 for inactivating the word line WL.

If an active command is applied and the word line WL is selected by an address, the driving device 210 drives the word line at a level of a pumping voltage VPP. Also, the word line WL can be driven with a power voltage VDD according to a scheme. Therefore, the word line WL is activated and all cell transistors, e.g., T connected to the word line WL in FIG. 1 are turned on to start an active operation. Thereafter, if a pre-charge command is applied, an operation of the driving device 210 is stopped and the driving device 220 drives the word line WL with a negative voltage VBBW. Therefore, the word line WL is inactivated and all the cell transistors T connected to the word line WL are turned off.

The word line is activated or inactivated through the above-mentioned operations, wherein the word line driving circuit for driving the word line WL may be configured in various types.

However, regardless of how the word line driving circuit is configured, there is no change in activation or deactivation of the word line WL as described above.

FIG. 3 is a diagram depicting one configuration method of the conventional word line driving circuit.

The word line driving circuit activates and inactivates a sub word line SWL in response to a main word line signal MWLB and a sub word line driving control signal FXB.

The main word line signal MWLB is enabled by a combination of desired addresses during an active operation. A plurality of sub word lines are subordinate to a single main word line. For instance, 8 sub word lines are bound by each of the main word lines (1:8 coding). Here, the sub word line SWL is a true word line to control the cell transistor T. That is, the word line WL shown in FIGS. 1 and 2 corresponds to the sub word line SWL.

The sub word line driving control signal FXB is a signal for selecting the sub word line SWL to be activated among the sub word lines subordinate to the main word line. For instance, if the sub word line SWL to be activated is selected by using total 10 addresses, the main word line to be activated among total 64, i.e., 2⁷, main word lines is selected by using 7 addresses and one among 8, i.e., 2³, sub word lines SWL subordinate to the activated main word line is selected by using the other 3 addresses.

Hereafter, an operation of the word line driving circuit shown in FIG. 3 will be described. If the main word line signal MWLB and the sub word line driving control signal FXB are activated to a logic low level, a transistor 301 and a transistor 303 are turned on. Therefore, the sub word line SWL is activated at a voltage level of the pumping voltage VPP. However, if any one of the main word line signal MWLB and the sub word line driving control signal FXB is inactivated to a logic high level, the sub word line SWL is inactivated at a voltage level of the negative voltage VBBW.

In other words, the sub word line SWL is activated only if both the main word line signal MWLB and the sub word line driving control signal FXB are activated and it is inactivated if any one of the two is inactivated.

Referring to FIG. 3 in view of FIG. 2, reference numerals ‘301’ and ‘303’ correspond to the driving unit 210 and reference numerals ‘305’ and ‘304’ correspond to the driving unit 220.

### SUMMARY OF THE INVENTION

The present invention has been proposed in order to overcome the above-described problems in the background of the present invention. Embodiments of the present invention are directed to providing a technology capable of reducing current consumption in a word line driving circuit.

Particularly, embodiments of the present invention are directed to providing a technology capable of reducing consumption of a negative voltage VBBW and a pumping voltage VPP in the word line driving circuit.

In accordance with an aspect of the present invention, there is provided a method for activating a word line inactivated with a negative voltage, including applying an intermediate voltage to the word line; and applying an activation voltage to the word line, wherein the intermediate voltage has a voltage level between the activation voltage and the negative voltage. In accordance with another aspect of the present invention, there is provided a method for inactivating a word line activated with an activation voltage, comprising: applying an intermediate voltage to the word line; and applying a negative voltage to the word line, wherein the intermediate voltage has a voltage level between the activation voltage and the negative voltage.

In accordance with still another aspect of the present invention, there is provided a method for driving a word line, including applying an intermediate voltage to the word line inactivated with a negative voltage signal in response to an active command; applying an activation voltage to the word line; applying the intermediate voltage to the word line in response to a pre-charge command; and applying the negative voltage to the word line, wherein the intermediate voltage has a voltage level between the activation voltage and the negative voltage.

In accordance with a further another aspect of the present invention, there is provided a circuit for driving a word line, including a first driving device configured to drive the word line with an activation voltage; a second driving device configured to drive the word line with an inactivation voltage; and a third driving device configured to drive the word line with a voltage between the activation voltage and the inactivation voltage.

In accordance with a further another aspect of the present invention, there is provided a circuit for driving a word line, including: a first word line driving driver configured to output a first word line driving control signal including address information for selecting a sub word line subordinate to a main word line; a second word line driving driver configured to supply a high voltage or an intermediate voltage to a voltage supply node in response to a second word line driving control signal generated by the same address as the first word line driving control signal; and a sub word line driver configured to drive the sub word line with a voltage at the voltage supply node or a negative voltage in response to the main word line signal and to drive the sub word line with the negative voltage in response to the first word line driving control signal, wherein the intermediate voltage has a voltage level between the high voltage and the negative voltage.

### BRIEF DESCRIPTION OF THE DRAWINGS

FIG. 1 illustrates a conventional memory cell of a semiconductor memory device.

FIG. 2 is a schematic diagram illustrating a conventional word line driving circuit.

FIG. 3 is a diagram depicting a conventional word line driving circuit.

FIG. 4 is a schematic diagram showing a word line driving circuit in accordance with an embodiment of the present invention.

FIG. 5 is a diagram illustrating an operation of the word line driving circuit shown in FIG. 4.

FIG. 6 is a detailed circuit diagram illustrating a word line driving circuit in accordance with an embodiment of the present invention.

FIG. 7 is a diagram illustrating an operation of the word line driving circuit shown in FIG. 6.

FIG. 8 is a diagram illustrating generating a first word line driving control signal FX1 and a second word line driving control signal FX2.

FIG. 9A is a diagram showing a current consumed in the word line driving circuit when using a conventional driving method.

FIG. 9B is a diagram illustrating a current consumed in the word line driving circuit when using a driving method of the present invention.

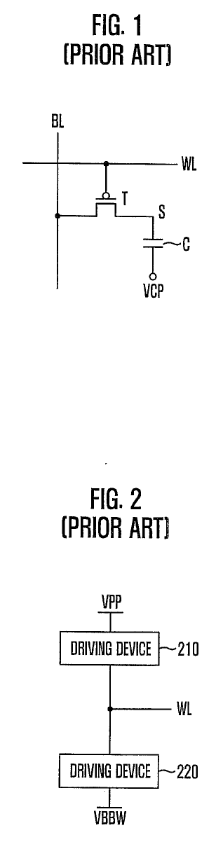

### DESCRIPTION OF SPECIFIC EMBODIMENTS

Other objects and advantages of the present invention can be understood by the following description, and become apparent with reference to the embodiments of the present invention.

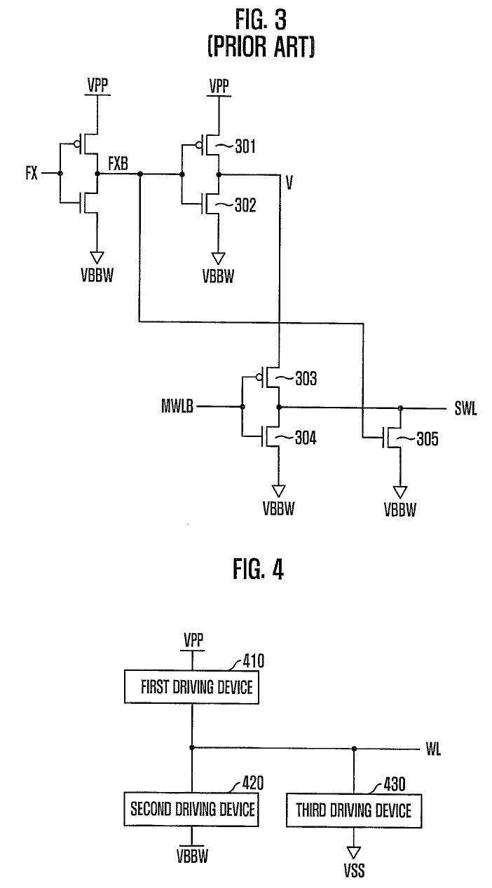

FIG. 4 is a schematic diagram showing a word line driving circuit in accordance with an embodiment of the present invention.

In accordance with the present invention, the word line driving circuit includes a first driving device 410 for driving a word line WL with a pumping voltage VPP or a power voltage VDD as an activation voltage, a second driving device 420 for driving the word line WL with a negative voltage VBBW as an inactivation voltage and a third driving device 430 for driving the word line WL with a voltage, e.g., a ground voltage VSS, between the activation voltage and the inactivation voltage.

The conventional word line driving circuit (see FIG. 2) includes only the first driving device 210 for driving the word line WL with the pumping voltage VPP or the power voltage VDD as the activation voltage and the second driving device 220 for driving the word line WL with the negative voltage VBBW as the inactivation voltage. Meanwhile, the word line driving circuit in accordance with the present invention further includes the third driving device 430 for driving the word line with the voltage between the activation voltage and the inactivation voltage, e.g., the ground voltage VSS.

In the conventional word line driving circuit, if the active command is applied and the word line WL to be driven is selected by the address, the selected word line WL is driven with the pumping voltage VPP as the activation voltage through the first driving device 210 and in this situation, if the pre-charge command is applied, the word line WL is driven with the inactivation voltage through the second driving device 220.

The word line driving circuit of the present invention operates in the same way as the conventional word line driving circuit. If an active command is applied and a word line WL to be driven is selected by an address, the word line WL is activated, and the word line WL is inactivated by a pre-charge command. However, the present invention has a characteristic that the third driving device 430 operates whenever states of the word line are changed from activation to inactivation and vice versa.

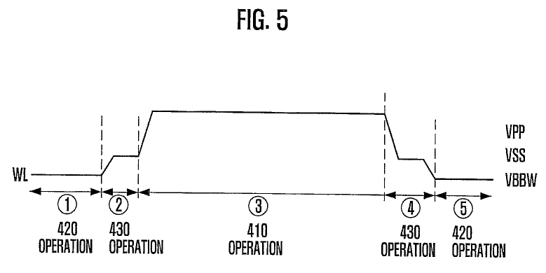

FIG. 5 is a diagram illustrating an operation of the word line driving circuit shown in FIG. 4. A method for driving the word line in accordance with the present invention and an operation effect thereof will be described with reference to FIG. 5.

At first, the second driving device 420 operates during a \textcircled{1} period where the word line WL is inactivated. That is, the negative voltage VBBW is applied to the word line WL.

If the active command is applied, the word line WL starts to be activated, wherein the third driving device 430 operates during a \textcircled{2} period where the word line WL starts to be activated. That is, the ground voltage VSS is applied to the word line WL. In the related art, as soon as the active command is applied, the pumping voltage VPP is applied to the word line WL through the first driving device 410. Therefore, this makes the pumping voltage VPP consumed much. However, in accordance with the present invention, the ground voltage VSS is applied to the word line WL by operating the third driving device 430 instead of the first driving device 410 during the \textcircled{2} period as an initial activation period of the word line WL. In short, the word line WL is inactivated to a very low level with the negative voltage VBBW and therefore, although the ground voltage VSS is applied, it is possible to increase a voltage of the word line WL. Since during the \textcircled{2} period, the ground voltage VSS is only applied through the third driving device 430, substantially a current is not consumed and no pumping voltage VPP is consumed during the \textcircled{2} period.

Although one example where the third driving device 430 drives the word line WL with the ground voltage VSS is shown in the drawing of the present invention, the third driving device 430 can be designed to drive the word line WL with an arbitrary voltage level between the negative voltage VBBW and the pumping voltage VPP as well as the ground voltage VSS. The present invention can reduce consumption of the negative voltage VBBW and the pumping voltage VPP even when the third driving device 430 drives the word line WL with 1/2 VDD. When the word line WL is driven with the ground voltage VSS, no current is consumed. Therefore, it is desirable that the third driving device 430 drives the word line WL with the ground voltage VSS.

After the \textcircled{2} period as the initial period for activating the word line WL, a \textcircled{3} period is started. The first driving device 410 operates during the \textcircled{3} period. In other words, the pumping voltage VPP is applied to the word line WL. If a power voltage VDD is used as an activation voltage of the word line WL instead of the pumping voltage VPP, the first driving device 410 drives the word line WL with the power voltage VDD during the \textcircled{3} period. The \textcircled{3} period is continued until the pre-charge command is applied.

If the pre-charge command is applied, an operation for inactivating the activated word line WL again is started. And, the third driving device 430 operates during a \textcircled{4} period where the word line WL starts to be inactivated. That is, the ground voltage VSS is applied to the word line WL. In the related art, as soon as the pre-charge command is applied, the negative voltage VBBW is applied to the word line WL. This makes the negative voltage VBBW consumed much. However, in accordance with the present invention, during the \textcircled{4} period as an initial inactivation period of the word line WL, the third driving device 430 instead of the second driving device 420 operates in order to apply the ground voltage VSS to the word line WL. Therefore, it is possible to lower the voltage of the word line WL without consuming the negative voltage VBBW.

After the \textcircled{4} period as the initial period for inactivating the word line WL, a \textcircled{5} period is started. The second driving device 420 operates during the \textcircled{5} period. That is, the negative voltage VBBW is applied to the word line WL. The \textcircled{5} period is continued until the active command is applied again.

The above-mentioned activation/inactivation operations of the word line WL are implemented on the assumption that driving periods of the second driving device 420 and the third driving device 430 do not overlap each other and driving periods of the first driving device 410 and the third driving device 430 do not overlap each other. Undoubtedly, it is preferable that as shown in the drawing, the driving periods do not overlap each other, however, even if the driving periods of the driving devices 410, 420 and 430 overlap one another slightly, the present invention can obtain the effect.

The word line driving circuit includes the first driving device 410, the second driving device 420 and the third driving device 430 as shown in FIG. 4 and the effect of the present invention can be achieved only by operating the word line driving circuit as shown in FIG. 5. The word line driving circuit which is constructed and operated as described above can be designed by various combinations according to a word line scheme. Hereafter, an example will be described in which the present invention is applied to a word line driving circuit which is designed to have superordinate and subordinate structures of a main word line and a sub word line.

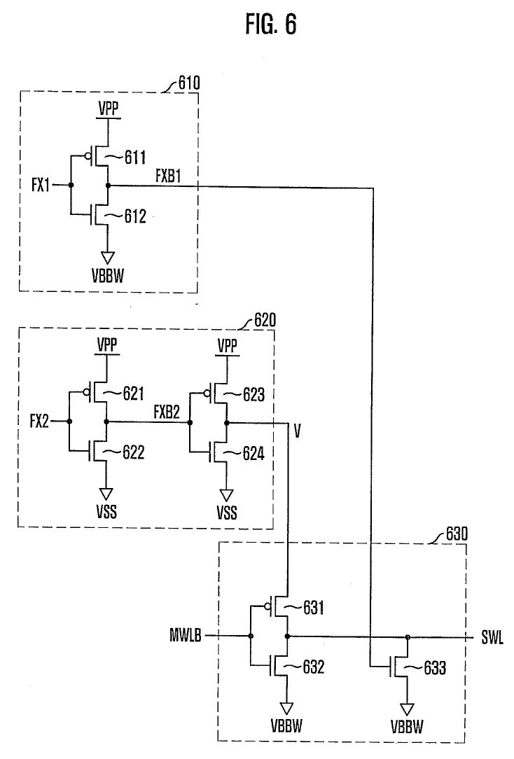

FIG. 6 is a detailed circuit diagram illustrating a word line driving circuit in accordance with an embodiment of the present invention.

In accordance with the present invention, a word line driver includes a first word line driving control driver 610, a second word line driving control driver 620 and a sub word line driver 630.

Before describing the components, signals shown in the drawing will be described. As described in the background of the invention, a main word line signal MWLB is a signal enabled by the combination of the desired addresses during an activate operation and a plurality of sub word lines SWL are bound in one main word line. The sub word line SWL is the true word line to control the cell transistor. That is, the word lines WL shown in FIGS. 4 and 5 correspond to the sub word line SWL shown in FIG. 6.

Sub word line driving control signals FXB1 and FXB2 are signals for selecting the sub word line SWL to be activated among the sub word lines SWL subordinate to the main word line. In the embodiment shown in FIG. 6, a first word line driving control signal FXB1 and a second word line driving control signal FXB2 are used, wherein the first and second word line driving control signals FXB1 and FXB2 are generated by the same combination of the addresses. In other words, a combination of the addresses to activate the first word line driving control signal FXB1 and a combination of the addresses to activate the second word line driving control signal FXB2 are equal to activate the sub word line SWL. The first and second word line driving control signals FXB1 and FXB2 are activated and inactivated at slightly different times.

The first word line driving control driver 610 outputs the first word line driving control signal FXB1 having address information to select the sub word line SWL subordinate to the main word line.

The second word line driving control driver 620 supplies the pumping voltage VPP or the ground voltage VSS to a voltage supply node V in response to the second word line driving control signal FXB2 which is generated by the same address as the first word line driving control signal FXB1.

The sub word line driver 630 drives the sub word line SWL with a supply voltage at the voltage supply node V or the negative voltage VBBW in response to the main word line signal MWLB and drives the sub word line SWL with the negative voltage VBBW in response to the first word line driving control signal FXB1.

Referring to FIG. 6 in view of FIG. 4, it is noticed that the first driving device 410 includes transistors 623 and 631, the second driving device 420 includes transistors 632 and 633, and the third driving device 430 includes transistors 624 and 631. This is because when the transistors 623 and 631 are turned on, the sub word line SWL is driven with the pumping voltage VPP, when the transistors 632 and 633 are turned on, the sub word line SWL is driven with the negative voltage VBBW, and when the transistors 624 and 631 are turned on, the sub word line SWL is driven with the ground voltage VSS.

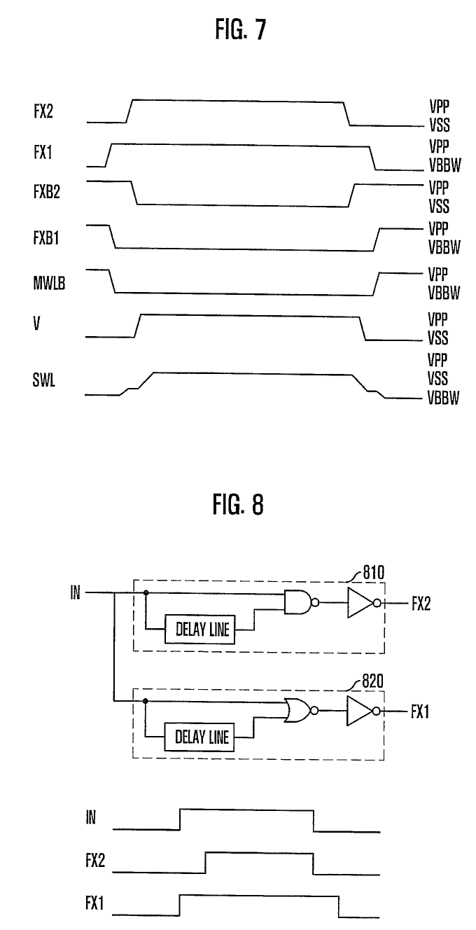

FIG. 7 is a diagram illustrating an operation of the word line driving circuit shown in FIG. 6. The operation of the word line driving circuit shown in FIG. 6 will be described in detail with reference to FIG. 7.

While the main word line signal MWLB is inactivated to a logic high level and the word line driving control signals FXB1 and FXB2 are inactivated to a logic high level, the transistors 632 and 633 are turned on in order to inactivate the sub word line SWL with the negative voltage VBBW (\textcircled{1} period).

If the active command is applied and the sub word line SWL is selected by the address, the main word line signal MWLB for controlling the sub word line SWL and the first word line driving control signal FXB1 are activated to a logic low level. At this time, the second word line driving control signal FXB2 is still inactivated to a logic high level. Therefore, the transistors 624 and 631 are turned on in order to drive the sub word line SWL with the ground voltage VSS (\textcircled{2} period).

Thereafter, the second word line driving control signal is activated to a logic low level. Therefore, the transistors 623 and 631 are turned on and the sub word line SWL is driven with the pumping voltage VPP (\textcircled{3} period).

If the pre-charge command is applied, the second word line driving control signal FXB2 is first inactivated to a logic high level. At this time, the first word line driving control signal FXB1 and the main word line signal MWLB are still activated to a logic low level. Therefore, the transistors 624 and 631 are turned on in order to drive the sub word line with the ground voltage VSS (\textcircled{4} period).

Thereafter, the main word line signal MWLB and the first word line driving control signal FXB1 are also inactivated to a logic high level. Therefore, the transistors 632 and 633 are turned on in order to drive the word line SWL with the negative voltage VBBW.

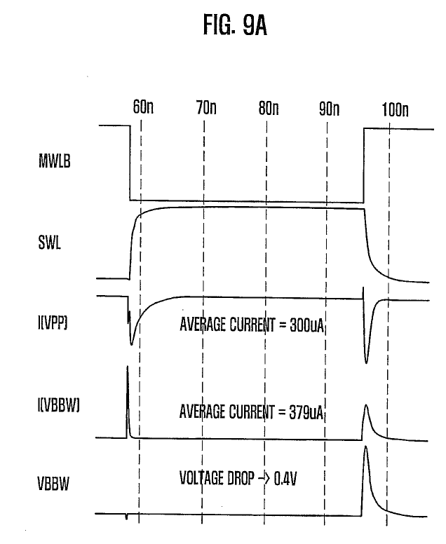

FIG. 8 is a diagram illustrating a method for generating a first word line driving control signal FX1 and a second word line driving control signal FX2.

The first word line driving control signal FX1 (a signal before inverted to FXB1) and the second word line driving control signal FX2 (a signal before inverted to FXB2) are generated by the same combination of addresses on the original signals IN. Here, the original signals IN are signals which are activated and inactivated by the combination of the addresses to select the sub word line SWL to be driven among the sub word lines SWL subordinate to the main word line. FX1 and FX2 may be driven at slightly different times as shown in FIG. 8 when they are activated and inactivated.

The original signals are delayed individually by using a rising delay circuit 810 and a falling delay circuit 820. Then, a signal passing through the rising delay circuit 810 is the second word line driving control signal FX2 and a signal passing through the falling delay circuit 820 is the first word line driving control signal FX1.

The original signal IN, the first word line driving control signal FX1 and the second word line driving control signal FX2 are shown in the bottom part of the drawing.

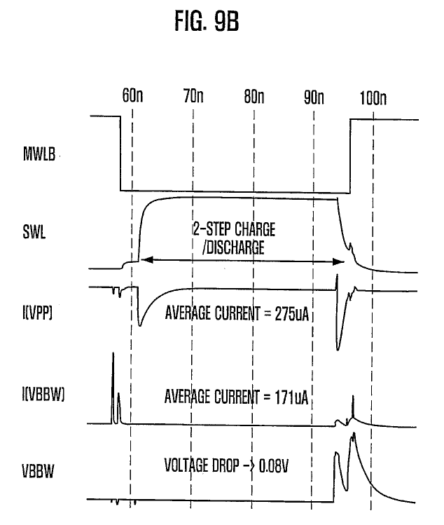

FIG. 9A is a diagram showing a current consumed in the word line driving circuit when using a conventional driving method and FIG. 9B is a diagram illustrating a current consumed in the word line driving circuit when using a driving method in accordance with the present invention.

When comparing the two drawings, it is noted that in the present invention, in case of the pumping voltage VPP, an average current consumption is reduced by 7.7% and a peak current is reduced and in case of the negative voltage VBBW, an average current consumption is reduced by 48.9% and a peak current is reduced to remarkably reduce a voltage drop of the negative voltage VBBW from 0.4V to 0.08V, thereby performing the very stable operation.

As described above, in the circuit and the method for driving the word line in accordance with the present invention, there is a period in which the word line is driven with the ground voltage when it is activated or inactivated.

Since when the word line is activated and inactivated, it is driven by using the ground voltage without the negative voltage or the pumping voltage during a predetermined period, the negative voltage or the pumping voltage is not consumed during the predetermined period. Therefore, the present invention can remarkably reduce the consumption of the current needed for driving the word line.

While the present invention has been described with respect to the specific embodiments, it will be apparent to those skilled in the art that various changes and modifications may be made without departing from the spirit and scope of the invention as defined in the following claims.

Particularly, it is natural that if the word line driving circuit proposed in the present invention includes the first driving device, the second driving device and the third driving device as shown in FIG. 4 and it is controlled as shown in FIG. 5, the present invention can reduce the amount of current consumption regardless of how the word line driving circuit is designed specifically.

What is claimed is:

1. A method for activating a word line inactivated with a negative voltage, comprising:
applying an intermediate voltage to the word line; and
applying an activation voltage to the word line, wherein the intermediate voltage has a voltage level between the activation voltage and the negative voltage.

2. The method of claim 1, wherein the intermediate voltage includes a ground voltage.

3. The method of claim 1, wherein the activation voltage is a power voltage or a pumping voltage higher than the power voltage.

4. The method of claim 1, wherein the word line activation is performed by applying an active command.

5. A method for inactivating a word line activated with an activation voltage, comprising:
applying an intermediate voltage to the word line; and
applying a negative voltage to the word line,
wherein the intermediate voltage has a voltage level between the activation voltage and the negative voltage.

6. The method of claim 5, wherein the intermediate voltage includes a ground voltage.

7. The method of claim 5, wherein the activation voltage is a power voltage or a pumping voltage above the power voltage.

8. A method for driving a word line, comprising:
applying an intermediate voltage to the word line inactivated with a negative voltage signal in response to an active command;
applying an activation voltage to the word line;
applying the intermediate voltage to the word line in response to a pre-charge command; and
applying the negative voltage to the word line,
wherein the intermediate voltage has a voltage level between the activation voltage and the negative voltage.

9. The method of claim 8, wherein the intermediate voltage includes a ground voltage.

10. The method of claim 8, wherein the activation voltage is a power voltage or a pumping voltage above the power voltage.

11. A circuit for driving a word line, comprising:
a first driving device configured to drive the word line with an activation voltage;
a second driving device configured to drive the word line with an inactivation voltage; and
a third driving device configured to drive the word line with a voltage between the activation voltage and the inactivation voltage.

12. The circuit for driving the word line of claim 11, wherein the third driving device operates during a predetermined period when activation and inactivation states of the word line are changed.

13. The circuit for driving the word line of claim 11, wherein the third driving device operates between an operation period of the first driving device and an operation period of the second driving device.

14. The circuit for driving the word line of claim 11, wherein a driving voltage of the first driving device is a pumping voltage higher than a power voltage, a driving voltage of the second driving device is a negative voltage and a driving voltage of the third driving device is a ground voltage.

15. A circuit for driving a word line, comprising:
a first word line driving driver configured to output a first word line driving control signal including address information for selecting a sub word line subordinate to a main word line;
a second word line driving driver configured to supply a high voltage or an intermediate voltage to a voltage supply node in response to a second word line driving control signal generated by the same address as the first word line driving control signal; and
a sub word line driver configured to drive the sub word line with a voltage at the voltage supply node or a negative voltage in response to a main word line signal and to drive the sub word line with the negative voltage in response to the first word line driving control signal,
wherein the intermediate voltage has a voltage level between the high voltage and the negative voltage.

16. The method of claim 15, wherein the intermediate voltage includes a ground voltage.

17. The circuit for driving the word line of claim 15, wherein the first word line driving control signal and the second word line driving control signal are activated and inactivated at different times.

18. The circuit for driving the word line of claim 15, wherein the second word line driving control signal is activated after activating the first word line driving control signal and inactivated after inactivating the first word line driving control signal.
